(19) United States
(12) Patent Application Publication
(10) Pub. No.: US 2026/0219309 A1
(43) Pub. Date: Jul. 30, 2026

(54) Method for detecting partial discharges in an insulator of an electrical conductor

(71) Applicant: Schneider Electric Industries SAS, Rueil Malmaison (FR)

(72) Inventors: Diego Alberto, Saint-Jean de Moirans (FR); Diana El Khoury, Grenoble (FR); Maxime Durand, Grenoble (FR)

(21) Appl. No.: 19/455,490

(22) Filed: Jan. 21, 2026

(30) Foreign Application Priority Data
Jan. 24, 2025 (EP) 25305090.0

(51) Int. Cl. G01R 31/12; G01R 19/00; G01R 19/04; G01R 25/00

(52) U.S. Cl. CPC G01R 31/1272; G01R 19/0053; G01R 19/04; G01R 25/00

(57) ABSTRACT

The invention relates to a method for detecting partial discharges in an insulator (2) of a medium-voltage electrical conductor (1),
comprising:
(i) acquiring a set (E) of samples of an electrical signal(S) representative of a partial discharge,
(ii) for each sample, determining the phase (P) of the alternating voltage,
(iii) establishing a matrix (M) of the number of samples for a set of signal amplitude ranges of the signal(S) and a set of ranges of phase values (P),
(iv) determining in the established matrix (M) a noisy zone (B), according to a condition based on:
   a statistical quantity representative of a number of values associated with a range of amplitude of the signal(S),
   a statistical quantity representative of a variability of the signal(S),
(v) replacing each element of the noisy zone (B) by a mathematical combination of elements outside the noisy zone (B) to form a corrected matrix (M-c),
(vi) detecting the presence of partial discharges from the corrected matrix (M-c).

### TECHNICAL FIELD

The present disclosure relates to the field of medium-voltage or high-voltage electrical devices, i.e. a voltage range from 1 kV to more than 52 kV.

### PRIOR ART

Electrical devices operating under medium voltage or high voltage can experience partial discharges between the electrical conductors and the surrounding environment. Partial discharge is understood to mean an electrical discharge localized in an electrical insulation. The discharge is said to be partial because it does not short-circuit the entire insulation. These partial discharges can propagate through the air, at the interface between the air and the insulator, or even inside the insulating material. These partial discharges have little short-term impact on the operation of the electrical device concerned, but accelerate the aging of the insulators. When the insulators are too damaged, a direct electrical arc can occur, which can lead to the destruction of the electrical device, prolonged power-down of parts of the electrical network, and can pose major risks to persons in the vicinity of the device. Partial discharges must therefore be detected in order to allow action to be taken to prevent permanent damage, destruction of the electrical device concerned, prolonged power interruption and personal injury.

A partial discharge can be detected from the signal supplied by a sensor to detect variations in the electrical field in the insulator surrounding an electrical conductor of the device. The sensor can, for example, be a capacitive coupler or an inductive sensor. Such a sensor generally supplies a low-amplitude signal, and the signal-to-noise ratio is generally unfavourable for accurate detection of partial discharges.

Some networks, for example incorporating direct-current power sources, such as wind or solar sources, can generate significant electrical noise because of the electronic power conversion components attached to these power sources. Detection of partial discharges is thus made more difficult, and both the non-detection rate and the false detection rate risk being degraded.

A need therefore exists for a method for detecting partial discharges that is more robust to the presence of electrical noise in the environment of the device being monitored.

### SUMMARY

To this end, the invention proposes a method for detecting partial discharges in an insulator of an electrical conductor of a medium-voltage or high-voltage electrical device, the electrical conductor being subjected to an alternating voltage,
the method comprising the steps of:
(i) successively acquiring a set of samples of an electrical signal representative of a partial discharge in the insulator of the electrical conductor,
(ii) for each sample in the set of samples, determining the value of the phase of the alternating voltage,
(iii) establishing a two-dimensional matrix of elements, wherein:
   a first dimension of the two-dimensional matrix corresponds to a set of ranges of values of the phase of the alternating voltage,
   a second dimension of the two-dimensional matrix corresponds to a set of ranges of amplitudes of the samples of the set of samples of the electrical signal, and
   the value of each element of the two-dimensional matrix is equal to the number of samples comprised within the value range of the phase of the alternating voltage associated with said element of the two-dimensional matrix and comprised within the amplitude range of the electrical signal associated with said element of the two-dimensional matrix,
(iv) determining in the two-dimensional matrix a portion corresponding to an electrical noise, called a noisy zone, according to a condition based on at least:
   a first statistical quantity representative of a number of values associated with a range of amplitude of the electrical signal,
   a second statistical quantity representative of a variability of the number of values associated with said range of amplitude of the electrical signal,
(v) for each element of the two-dimensional matrix that is part of said noisy zone, replacing the value of said element by the result of a mathematical function of at least:
   a first element of the two-dimensional matrix located outside the noisy zone, called the first reference element, the first reference element being associated with:
      the same value range of the phase of the electrical voltage as said element, and associated with
      an amplitude range below the amplitude range of said element, and
   a second element of the two-dimensional matrix located outside the noisy zone, called the second reference element, the second reference element being associated with:
      the same value range of the phase of the electrical voltage as said element, and associated with
      an amplitude range above the amplitude range of said element,
in order to establish a two-dimensional corrected matrix of elements,
(vi) detecting the presence of partial discharges or the absence of partial discharges in the insulator from the established corrected matrix.

By identifying a noisy zone in the matrix, and by replacing the value of each element of the identified noisy zone by a mathematical calculation performed on elements surrounding said element of the noisy zone, the noise can be reduced or even eliminated from the matrix. The partial discharge detection algorithm can continue processing with data of which the noise has been at least reduced.

The number and relative arrangement of elements taken into account in calculating the replacement value of each element forming part of the noisy zone can vary.
The initial presence of noise superimposed on the real signal from partial discharges creates a risk of partial discharges not being detected, as well as a risk of false detections.
The proposed method includes signal processing steps to reduce or eliminate the effect of noise. The accuracy of the partial discharge detection step is thus improved. Both the non-detection rate and the false detection rate can be improved.
By using simple mathematical combinations, such as averaging, the computational resources required remain limited. The detection method can be easily implemented in equipment having limited hardware resources.

The features listed in the following paragraphs can be implemented independently from one other or in any technically feasible combination:

The electrical signal is an output voltage of a capacitive coupler.

The electrical signal is an output voltage of an inductive coupler.

The sampling frequency of the electrical signal is between 20 MHz and 100 MHz.

The two-dimensional matrix is a two-dimensional rectangular array.

The set of samples of the electrical signal is acquired during a predetermined time period.

The value of each element of the two-dimensional matrix can be a number of samples acquired during a predetermined acquisition period.

The value of each element of the two-dimensional matrix can be a number of samples acquired per unit of time.

The set of value ranges of the phase of the electrical voltage includes a fixed number of values ranges.

The n value ranges of the phase are contiguous.

The n values ranges of the phase have the same width.

The set of amplitude ranges of the samples of the electrical signal comprises a fixed number of ranges.

The amplitude ranges of the samples are contiguous.

The amplitude ranges of the samples have the same width.

The portion of the matrix corresponding to noise, called the noisy zone, comprises a subset of the elements of the two-dimensional matrix.

According to one embodiment of the method for detecting partial discharges, for each element of the two-dimensional matrix forming part of said noisy zone:
the first reference element is associated with the amplitude range immediately below the amplitude range of said element, and
the second reference element is associated with the amplitude range immediately above the amplitude range of said element.

An element of the matrix forming part of the noisy zone is replaced by a value directly correlated with the values of the nearest elements not forming part of the noisy zone.

According to one embodiment of the method for detecting partial discharges, for each element of the two-dimensional matrix forming part of said noisy zone, the value of said element is replaced by the result of a mathematical function of at least:
a group of first elements of the two-dimensional matrix located outside the noisy zone, referred to as the group of first reference elements, each element of the group of first reference elements being respectively associated with an amplitude range below the amplitude range of said element, and
a group of second elements of the two-dimensional matrix located outside the noisy zone, referred to as the group of second reference elements, each element of the group of second reference elements being respectively associated with an amplitude range above the amplitude range of said element.

According to one embodiment, the amplitude ranges of the group of first reference elements are consecutive ranges, and
the amplitude ranges of the group of second reference elements are consecutive ranges.

According to one embodiment of the proposed method, for each element of the two-dimensional matrix forming part of said noisy zone:
each element of the group of first reference elements is respectively associated with the same value range of the phase of the electrical voltage as said element, and:
each element of the group of second reference elements is respectively associated with the same value range of the phase of the electrical voltage as said element.

According to another embodiment of the method for detecting partial discharges, for each element of the two-dimensional matrix forming part of said noisy zone:
at least one element of the group of first reference elements is associated with a phase value range different from the phase value range of said element, and:
at least one element of the group of second reference elements is assigned a phase value range different from the phase value range of said element.

According to one embodiment of the method for detecting partial discharges, the first statistical quantity representative of a number of values associated with an amplitude range of the electrical signal is a mean value of the samples of the electrical signal,
the mean value being determined over a subset of the phase value ranges of the electrical voltage.

According to another embodiment of the method for detecting partial discharges, the first statistical quantity representative of a number of values associated with an amplitude range of the electrical signal is a mean value of the values of the elements of the two-dimensional matrix associated with said amplitude range of the electrical signal,
the mean being determined over the set of ranges of phase values of the alternating voltage.

The mean value is a weighted arithmetic mean.

The mean value is the arithmetic mean.

According to another embodiment, the mean value is the geometric mean.

According to one embodiment of the method for detecting partial discharges, the second statistical quantity representative of a variability of the number of values associated with said amplitude range of the electrical signal is a standard deviation of the values of the elements of the two-dimensional matrix associated with said amplitude range of the electrical signal,
the standard deviation being determined over a subset of the phase value ranges of the alternating voltage.

According to another embodiment of the method for detecting partial discharges, the second statistical quantity representative of a variability of the number of values associated with said amplitude range of the electrical signal is a standard deviation of the values of the elements of the two-dimensional matrix associated with said amplitude range of the electrical signal,
the standard deviation being determined over the set of ranges of phase values of the alternating voltage.

According to another embodiment of the method for detecting partial discharges, the second statistical quantity representative of a variability of the number of values associated with said amplitude range of the electrical signal is a variance of the samples of the electrical signal,
the variance being determined over a subset of the phase value ranges of the current.

According to another embodiment of the method for detecting partial discharges, the second statistical quantity representative of a variability of the number of values associated with said amplitude range of the electrical signal is a variance of the samples of the electrical signal,
the variance being determined over the set of ranges of phase values of the current.

According to one variant, the second statistical quantity representative of a variability of the number of values associated with said amplitude range of the electrical signal is a difference between a maximum value determined over a subset of the phase value ranges of the electrical voltage and a minimum value determined over said subset of the phase value ranges of the electrical voltage.

According to one variant, the second statistical quantity representative of a variability of the number of values associated with said amplitude range of the electrical signal is a difference between a maximum value determined over the set of ranges of phase values of the electrical voltage and a minimum value determined over the set of ranges of phase values of the electrical voltage.

The determined difference can be an absolute difference.

The determined difference can be a relative difference.

According to one embodiment of the method for detecting partial discharges, in step (iv), an element of the two-dimensional matrix is part of said noisy zone if:
the first statistical quantity, determined for the amplitude range of said element, is greater than a first threshold, and
the second statistical quantity, determined for the amplitude range of said element, is less than a second threshold.

The noise to be processed has the feature of being of a relatively high level, this level further being relatively constant according to the phase of the voltage. The amplitude varies relatively little from one phase value range to another phase value range. The first condition of having the first statistical quantity above a threshold indicates that the noise level is relatively high. The second condition of having the second statistical quantity below a threshold indicates that the variability according to the phase of this noise level is low. Both conditions must be met simultaneously.

According to one embodiment of the method for detecting partial discharges, in step (iv), an element of the two-dimensional matrix is part of said noisy zone if a ratio of:
the first statistical quantity, determined for the amplitude range of said element, and of
the second statistical quantity, determined for the amplitude range of said element, is greater than a predetermined third threshold.

Rather than having two different conditions, each based on one of the statistical quantities, a condition based on a ratio of these two statistical quantities can be used. A single threshold must be defined, which makes it easier to calibrate the method.

According to an alternative embodiment of the method for detecting partial discharges, in step (iv), an element of the two-dimensional matrix forms part of said noisy zone if a ratio of:
the first statistical quantity, determined for the amplitude range of said element, and of
the maximum value between:
   the second statistical quantity, determined for the amplitude range of said element, and
   a predetermined constant,
      is greater than a predetermined third threshold.

By taking the maximum between the second statistical quantity and a constant value, the cases entailing a risk of indeterminacy in the calculation are eliminated. Indeterminacy is understood to mean the ratios, or fraction, wherein both the numerator and the denominator of the fraction formed are close to zero.

The predetermined constant is, for example, one hundredth of the number of amplitude ranges of the two-dimensional matrix, rounded up to the nearest integer.

The predetermined constant is, for example, 1.

According to one embodiment of the method for detecting partial discharges, in step (iv), the noisy zone of the two-dimensional matrix comprises the set of ranges of phase values of the current.

According to one embodiment of the method for detecting partial discharges, in step (v), the value of each element of the two-dimensional matrix that is part of the noisy zone is replaced by a weighted mean of the value of the element associated with:
the same phase value range of the alternating voltage phase, and with
the amplitude range immediately below the amplitude range of said element,
   and of the value of the element associated with:
the same phase value range of the alternating voltage phase, and with
the amplitude range immediately above the amplitude range of said element.

The weighting factors can be identical. In other words, the weighted mean can be the arithmetic mean.

The weighting coefficients can be different. In other words, greater importance can be attached to one of the two elements surrounding the element of which the value is corrected in order to reduce noise.

The mean can be the geometric mean.

According to one particular embodiment of the method for detecting partial discharges, in step (v), the value of each element of the two-dimensional matrix that is part of the noisy zone is replaced by an arithmetic mean of:
the value of the element associated with the same phase value range of the alternating voltage, and the amplitude range immediately below the amplitude range of said element, and
the value of the element associated with the same phase value range of the alternating voltage, and with the amplitude range immediately above the amplitude range of said element.

According to one embodiment of the method for detecting partial discharges, the scale of the units of the electrical signal representative of a partial discharge in the insulator of the electrical conductor is a logarithmic scale.

The invention also relates to a method for detecting partial discharges in a medium-voltage or high-voltage electrical device,
the electrical device comprising:
   a first electrical conductor comprising an insulator,
   a second electrical conductor comprising an insulator,
   a third electrical conductor comprising an insulator,
the first electrical conductor, the second electrical conductor and the third electrical conductor corresponding respectively to a first phase, a second phase and a third phase of an electrical network,
wherein a method as described above is carried out for the insulator of each electrical conductor.

The invention also relates to a device for detecting partial discharges, comprising:
a sensor configured to supply an electrical signal representative of a partial discharge in an insulator of an electrical conductor,
an electronic control unit configured to carry out the method for detecting partial discharges as described above.

In one embodiment, the device for detecting partial discharges comprises:
three sensors, each sensor being configured to supply an electrical signal representative of a partial discharge in an insulator of an electrical conductor,
an electronic control unit configured to carry out the method for detecting partial discharges as described above.

the invention also relates to a medium-voltage or high-voltage electrical device, the electrical device comprising:
an electrical conductor,
an insulator surrounding the electrical conductor,
a sensor configured to supply an electrical signal representative of a partial discharge in the insulator of the electrical conductor,
an electronic control unit configured to carry out the method for detecting partial discharges described above.

According to one embodiment, the medium-voltage or high-voltage electrical device comprises:
three electrical conductors corresponding respectively to three phases of a three-phase medium-voltage or high-voltage electrical network,
three insulators, each insulator surrounding an electrical conductor,
three sensors, each sensor being respectively configured to supply an electrical signal representative of a partial discharge in the insulator of an electrical conductor,
an electronic control unit configured to carry out, for each insulator, the method for detecting partial discharges as described above.

### BRIEF DESCRIPTION OF THE DRAWINGS

Other features, details and advantages will become evident from a reading of the detailed description below, and from an analysis of the attached drawings, wherein:

FIG. 1 is a schematic representation of a medium-voltage or high-voltage electrical device, on which the proposed method can be carried out,

FIG. 2 is a diagram illustrating certain steps of the proposed method,

FIG. 3 is another diagram illustrating other steps of the proposed method,

FIGS. 4A and 4B are another example of the diagram shown in FIG. 3,

FIGS. 5A and 5B are another diagram illustrating other steps of the method,

FIGS. 6A and 6B are another example of the diagram shown in FIG. 5A and FIG. 5B,

FIGS. 7A and 7B are another diagram illustrating other steps of the proposed method,

FIGS. 8A and 8B are another example of the diagram shown in FIG. 7A and FIG. 7B,

FIG. 9 is yet another example of the diagram shown in FIG. 7A and FIG. 7B,

FIG. 10 is a block diagram of the proposed method.

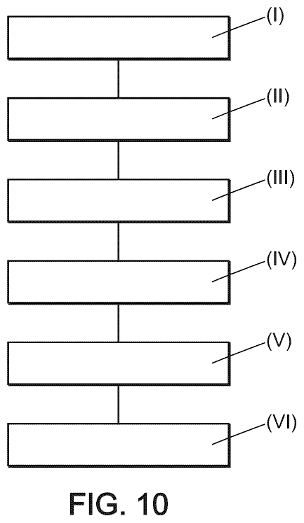

### DESCRIPTION OF THE EMBODIMENTS

In order to facilitate the reading of the figures, the different elements are not necessarily shown to scale. Identical elements are denoted with the same reference signs in these figures. Certain elements or parameters can be indexed, i.e. designated, for example, as the first element or second element, or as the first parameter and second parameter, etc. The purpose of this indexing is to differentiate elements or parameters that are similar but not identical. This indexing does not imply a priority of one element or parameter over another, and the denominations can be interchanged. When it is specified that a device comprises a given element, this does not exclude the presence of other elements in this device.

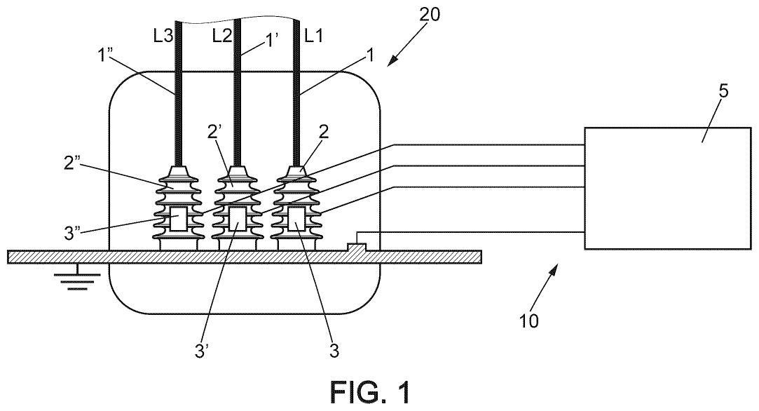

FIG. 1 shows schematically a medium-voltage or high-voltage electrical device 20.

The electrical device 20 comprises:
an electrical conductor 1,
an insulator 2 surrounding the electrical conductor 1,
a sensor 3 configured to supply an electrical signal S representative of a partial discharge in the insulator 2 of the electrical conductor 1.
   The electrical device 20 also comprises an electronic control unit 5 configured to carry out a method for detecting partial discharges according to the invention, which will be described in detail below.

More specifically, the medium-voltage or high-voltage electrical device 20 comprises:
three electrical conductors 1, 1′, 1″ corresponding respectively to three phases L1, L2, L3 of a three-phase medium-voltage or high-voltage electrical network,
three insulators 2, 2′, 2″, each insulator 2, 2′, 2″ surrounding respectively an electrical conductor 1, 1′, 1″,
three sensors 3, 3′, 3″, each sensor 3, 3′, 3″ being respectively configured to supply an electrical signal S, S′, S″ representing a partial discharge in the insulator 2, 2′, 2″ of an electrical conductor 1, 1′, 1″.
   The electronic control unit 5 of the electrical device 20 is configured to carry out, for each insulator 2, 2′, 2″, the method for detecting partial discharges according to the invention.

In other words, each of the three electrical conductors 1, 1′, 1″ is respectively surrounded by an insulator 2, 2′, 2″. The electrical device 20 comprises three partial discharge sensors 3, 3′, 3″, i.e. one partial discharge sensor for each of the three phases L1, L2, L3.

Each partial discharge sensor is, for example, a capacitive sensor.
Each partial discharge sensor can also be an inductive sensor.

The phase of the voltage varies, by convention, between 0° and 360° (degrees of angle) for each of the electrical conductors. The phase expresses the periodic variations of the voltage, the variation period being reduced to an angular range from 0° to 360°. The terms “phase of the voltage” and “phase angle of the voltage” are equivalent.

The voltage is phase-shifted through 120° between two electrical conductors.

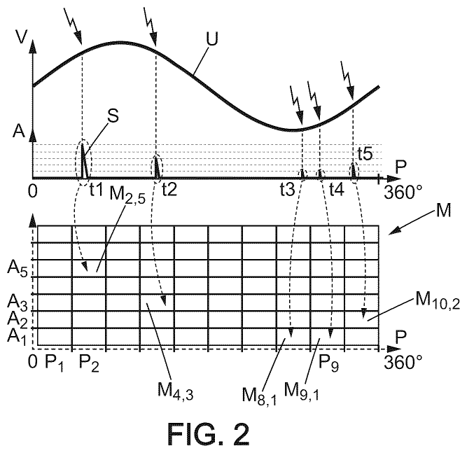

The upper part of FIG. 2 shows schematically the partial discharge phenomenon in the insulator 2 of an electrical conductor 1.

The curve denoted by the sign U illustrates the variations of the electrical voltage to which the electrical conductor is subjected, according to the phase P of the voltage.
This phase P varies between 0° and 360°.

The invention proposes a method for detecting partial discharges in an insulator 2 of an electrical conductor 1 of a medium-voltage or high-voltage electrical device 20, the electrical conductor 1 being subjected to an alternating voltage U.

The proposed method comprises the step of:
(i) successively acquiring a set E of samples of an electrical signal S representative of a partial discharge in the insulator 2 of the electrical conductor 1.
   The proposed method comprises the step of:
(ii) for each sample in the set E of samples, determining the value of the phase P of the alternating voltage.
   The proposed method comprises the step of:
(iii) establishing a two-dimensional matrix M of elements M_{I,j}, wherein:
   a first dimension of the two-dimensional matrix M corresponds to a set of ranges of values of the phase P of the alternating voltage,
   a second dimension of the two-dimensional matrix M corresponds to a set of amplitude ranges of the samples of the set E of samples of the electrical signal S, and
   the value of each element M_{I,j} of the two-dimensional matrix M is equal to the number of samples included in the value range of the phase P of the alternating voltage associated with said element of the two-dimensional matrix M and included in the amplitude range of the electrical signal S associated with said element of the two-dimensional matrix M.
      The proposed method comprises the step of:
(iv) determining, in the established two-dimensional matrix M, a portion B corresponding to electrical noise, referred to as the noisy zone B, according to a condition based on at least:
   a first statistical quantity G1 representative of a number of values associated with an amplitude range of the electrical signal S,
   a second statistical quantity G2 representative of a variability of the number of values associated with said amplitude range of the electrical signal S.
      The proposed method comprises the step of:
(v) for each element M_{I,j} of the two-dimensional matrix M forming part of said noisy zone B, replacing the value of said element M_{I,j} with the result of a mathematical function of at least:
   a first element of the two-dimensional matrix M located outside the noisy zone B, called the first reference element R1, the first reference element R1 being associated with:
      the same value range of the phase P of the electrical voltage as said element M_{I,j}, and associated with
      an amplitude range below the amplitude range of said element M_{I,j}, et
   a second element of the two-dimensional matrix M located outside the noisy zone B, called the second reference element R2, the second reference element R2 being associated with:
      the same value range of the phase P of the electrical voltage as said element M_{I,j}, and associated with
      an amplitude range above the amplitude range of said element M_{I,j},
in order to establish a two-dimensional corrected matrix M_CoR of elements.
   The proposed method comprises the step of:
(vi) detecting the presence of partial discharges or the absence of partial discharges in the insulator 2 on the basis of the established corrected matrix M_CoR.

The first steps of the method aim to establish a matrix M of the number N of acquired samples, according to their amplitude A and their phase P. A part, or certain parts, of this matrix M can correspond to electrical noise, and not to a usable signal. Such electrical noise risks generating false detections and/or non-detections of partial discharges.

The proposed method can identify at least one noisy zone B in the established two-dimensional matrix M. The values of the identified noisy zone B are replaced on the basis of a mathematical calculation performed on elements of the matrix surrounding this noisy zone B, but located outside this noisy zone B. The noise can thus be reduced or even eliminated from the matrix M. The partial discharge detection algorithm can continue processing with a corrected matrix of data having a reduced noise level.
By using simple mathematical combinations, such as averaging, the computational resources required remain limited. The detection method can thus be simply carried out in equipment having limited hardware resources.
The replacement value of the elements M_{I,j} of the two-dimensional matrix M forming part of the noisy zone B is determined from the value of at least two adjacent elements located outside the noisy zone, and more than two adjacent elements can be taken into account, as described below.

According to the example shown, the electrical signal S is an output voltage of a capacitive coupler.

The electrical signal S is obtained through capacitive coupling between the measurement sensor 3 and the insulator 2 of the electrical conductor 1.

According to one alternative embodiment (not shown), the electrical signal S is an output voltage of an inductive coupler.

The electrical signal S is obtained through inductive coupling between the measurement sensor 3 and the insulator 2 of the electrical conductor 1.

The electrical signal S is sampled. The sampling frequency of the electrical signal is between 20 MHz and 100 MHz.

FIG. 2 shows the acquisition of the signal S and the formation of the two-dimensional matrix M.

The upper part of FIG. 2 shows the voltage U to which the electrical conductor 1 and the insulator 2 are subjected, as well as the signal S delivered by the partial discharge sensor.
The x-axis corresponds to the phase P, and the y-axis corresponds to the voltage U and the signal S. The curves representative of signal S and voltage U are not shown to scale.
The curve shown corresponds to a single period of the signal.

At the time corresponding to the phase indicated by the sign t1, a first partial discharge occurs in the insulator. The amplitude A of the associated signal corresponds to 5 tiles, the scale chosen being purely illustrative.

At the time corresponding to the phase indicated by the sign t2, a second partial discharge occurs, with a lower amplitude, corresponding to an amplitude of 3 tiles.
Two other partial discharges, having an amplitude of 1, occur respectively at the phases indicated by the signs t3 and t4. In the example shown in FIG. 2, a final partial discharge occurs for the phase t5, having an amplitude of 2 tiles.

Each partial discharge is recorded in a two-dimensional matrix M.

The two-dimensional matrix M is a rectangular two-dimensional array.
The array comprises a set of horizontal rows, and a set of vertical columns.
An element M_{I,j} is disposed at the intersection of column i and row j.
Each element M_{I,j} of the two-dimensional matrix M is associated with:
a value range of the phase P of the alternating voltage, and
an amplitude range of the electrical signal S.
   The value of an element M_{I,j} of the two-dimensional matrix M is the number of samples N of which:
the amplitude belongs to the corresponding amplitude range Aⱼ, and
the phase belongs to the corresponding value range of the phase P_{I}.

By way of example, a sample having a phase of 105° and an amplitude of 5 is recorded by the element associated with the phase range [100°, 120°] and the amplitude range [4, 8].

A sample having a phase of 110° and an amplitude of 7 is also recorded by the same element of the matrix.
A sample having a phase of 165° and an amplitude of 3 is recorded by the element associated with the phase range [160°, 180°] and the amplitude range [0, 4].

The set of value ranges of the phase P of the electrical voltage here comprises a fixed number of value ranges. This number is denoted here by n. The terms ‘value ranges of the phase P’ and ‘value ranges of the phase P’ are equivalent.

The n value ranges of the phase P are arranged in ascending order.

The n value ranges of the phase P are contiguous.
In other words, the upper limit of a range is equal to the lower limit of the range immediately above it, when that range exists. Similarly, the lower limit of a range is equal to the upper limit of the range immediately below it, when that range exists.
The lower limit of the first range corresponds to the minimum value of the set of values, i.e. 0°. The upper limit of the last range corresponds to the maximum value of the set of values, i.e. 360°.

The n ranges of values of the phase P preferably have the same width.

For example, the total extent of the phase values is divided into 24 ranges of 15°. The first range covers values from 0° to 15°, the second range covers the values from 15° to 30°, the third range covers the values from 30° to 45°, and so on.
According to another example, the total extent of the phase values is divided into 120 ranges of 3°.
To simplify FIG. 2, the set of value ranges of the phase P comprises 10 ranges, corresponding to 10 columns of matrix M.

The set of amplitude ranges of the samples of the electrical signal S comprises a fixed number of ranges. This number is denoted by m. The terms ‘amplitude ranges’ and ‘amplitude value ranges’ are equivalent.

The m amplitude ranges enabling the distribution of the samples are arranged in ascending order.

The m amplitude ranges of the samples are contiguous. As above, the upper limit of a range is equal to the lower limit of the range immediately above it.
The m amplitude ranges of the samples have the same width.

In the example shown FIG. 2, the different value ranges of the phase P correspond to the different columns of the matrix. In a column, the amplitude ranges are arranged in ascending order, and the range of the phase P does not vary. The first range P₁, the second range P₂ and the ninth range P₉ are shown.

In this FIG. 2, the different amplitude ranges of the samples correspond to the rows of the matrix M. In a row, the ranges of the phase P are arranged in ascending order, and the amplitude range does not vary.
The first range A₁, the second range A₂, the third range A₃ and the fifth range A₅ are shown.
The two-dimensional matrix M therefore comprises the product of n*m elements. Each element M_{I,j} is referenced in the matrix M by two independent indices i and j, with i varying from 1 to n and j varying from 1 to m.
According to one example (not shown), it is obviously possible to transpose the matrix M, i.e. to interchange the roles of the rows and columns of the matrix.

Each acquired sample is associated with an amplitude of the electrical signal S and with a phase P of the electrical voltage U at the time of acquisition.

Each sample comprises a pair of values:
one value is the amplitude of the electrical signal S representative of a partial discharge, corresponding to a given acquisition time, and
the other value is the value of the phase of the electrical voltage U at the same acquisition time.
   Two distinct samples correspond to two distinct acquisition times.

The lower part of FIG. 2 shows how the matrix M is established.

The partial discharge having occurred at time t1 falls within the second phase range P₂ and the fifth amplitude range A₅.
The partial discharge having occurred at time t2 falls within the fourth phase range P₄ and the third amplitude range A₃.

The partial discharges at time t3 and time t4 both fall within the first amplitude range A₁, and into the eighth phase range P₈ and the ninth phase range P₉ respectively.

For each partial discharge, the corresponding element of the two-dimensional matrix M is incremented by 1. The element M_{2,5} is thus incremented by 1 due to the partial discharge at time t1, the element M_{4,3} is incremented due to the partial discharge at time t2, the element M_{8,1} is incremented by 1 due to the partial discharge at time t3, the element M_{9,1} is incremented by 1 due to the partial discharge at time t4 and the element M_{10,2} is incremented by 1 due to the partial discharge at time t5.

The set E of samples of the electrical signal S is acquired during a predetermined time period.

For example, the electrical signal S of the partial discharge sensor 3 is acquired during 30 consecutive minutes.
For each period of the electrical voltage, the measurement samples acquired during this period are added to the matrix M that is already formed.
The number of measurement samples included in the matrix M therefore increases regularly during the data acquisition.
The acquisition time period is adapted to the sampling frequency that is used.

The value of each element M_{I,j} of the two-dimensional matrix M can be a number of samples acquired during a predetermined acquisition time period.

For example, the value of each element M_{I,j} of the two-dimensional matrix M can be the number of samples acquired over a 30-minute period.

The value of each element M_{I,j} of the two-dimensional matrix M can also be a number of samples acquired per unit of time.

For example, the value of each element M_{I,j} of the two-dimensional matrix M can be the number of samples per second falling within the amplitude range and phase range pair corresponding to the element M_{I,j}.

The procedure for establishing the two-dimensional matrix M is generally referred to by the acronym ‘PRPD’ (‘Phase Resolved Partial Discharge’).

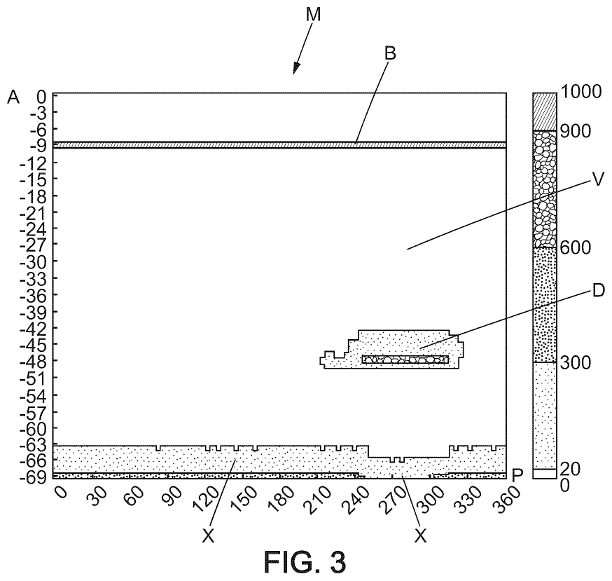

FIG. 3 is a graphical representation of an example of a formed matrix, here after a 30-minute acquisition period.

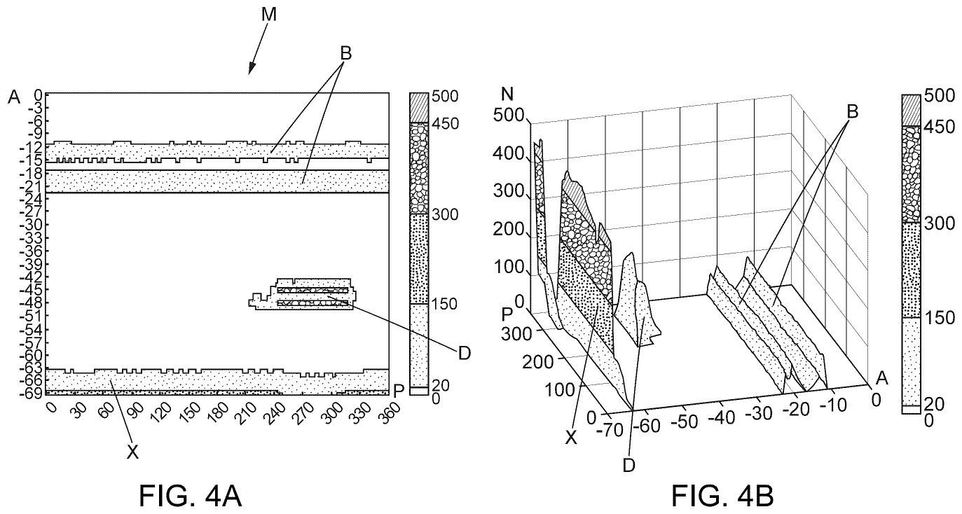

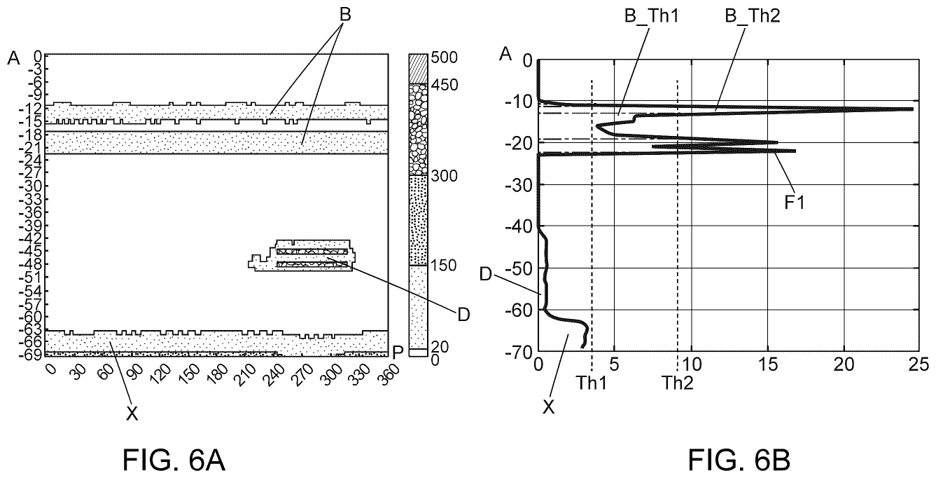

In this representation, the number N of samples corresponding to a given element of the matrix is represented by the pattern employed.
In order to simplify the figure, only five value ranges of N have been shown.
The first range, corresponding to the lowest amplitudes, is represented by a white background.
Thus, all of the elements for which the associated number of samples is close to zero are in white.
The same representation code is used for FIG. 4A and FIG. 4B and FIG. 6A and FIG. 6B.

According to the example shown in FIG. 3, the scale of the units of the electrical signal S representative of a partial discharge in the insulator 2 of the electrical conductor 1 is a logarithmic scale.

The electrical signal S corresponds here to 20 times the logarithm of the ratio of the output voltage of the sensor 3 and of a reference voltage.
The unit of the electrical signal S is therefore the decibel. (DB)

Here, the set of amplitude ranges of the samples of the electrical signal S comprises 70 ranges.

The width of a range is 1 unit here.
The scale varies between −69 dB, for signals having a lower amplitude, and 0 dB, for signals having a higher amplitude.

In FIG. 3, most of the matrix M, designated by the sign V, corresponds to elements comprising a very small number of samples, this number being almost zero.

The zone designated by the sign D corresponds to the part that is really representative of the partial discharges. It should be noted that partial discharges occur for phase values varying relatively little, these values varying between approximately 220° and 330°. Similarly, the associated amplitude is centred around −45 dB.
The zone designated by the sign X corresponds to a very low amplitude A of the signal, and does not correspond to a partial discharge. This part of the matrix M is to be retained.
The part designated by B corresponds to noise. In other words, this part of the elements of the matrix M does not correspond to partial discharges, but to electrical noise linked to the environment of the partial discharge sensor 3. The electrical device 20, or other electrical devices located near to the electrical device 20, can in fact comprise switching elements that generate high noise, such as rectifiers or choppers.
This electrical noise is not linked to the phase P of the alternating voltage U in the conductor 1 for which the partial discharges in the insulator 2 are analysed, and appears as a continuous line on the diagram representing the elements of the matrix M.
In the example shown in FIG. 3, the noisy zone B appears in the form of a thin horizontal line, since this noisy zone B comprises a single amplitude range.

FIG. 4A is a graphical representation of another example of a formed matrix, corresponding to another example.

FIG. 4B is a three-dimensional representation of the matrix of FIG. 4A.
The two axes A, P in the horizontal plane correspond to the amplitude ranges A of the signal and to the value ranges of the phase P. The vertical axis N corresponds to the number of samples for each amplitude range A_{I} and each value range of the phase Pⱼ.
The noisy zone B extends over a wider band of amplitude ranges than in the case of FIG. 3, and partially covers a plurality of amplitude ranges, extending approximately from −25 dB to −10 dB.

The portion of the matrix M corresponding to noise, referred to as the noisy zone B, thus comprises a subset of the elements of the two-dimensional matrix M.

Once the noisy zone B is identified, the elements forming this noisy zone B are replaced by other values, derived from the value of the elements adjacent to the noisy zone B but not forming part of this noisy zone B.

According to one embodiment of the method for detecting partial discharges, for each element M_{I,j} of the two-dimensional matrix M forming part of said noisy zone B:
the first reference element R1 is associated with the amplitude range immediately below the amplitude range of said element M_{I,j}, et
the second reference element R2 is associated with the amplitude range immediately above the amplitude range of said element M_{I,j}.
   For an element M_{I,j}, associated with the amplitude range Aⱼ, the amplitude range immediately below it is the amplitude range Aⱼ₋₁. The amplitude range immediately above it is the amplitude range Aⱼ₊₁.

An element of the matrix M forming part of the noisy zone B is thus replaced by a value directly correlated with the values of the nearest elements not forming part of the noisy zone B.

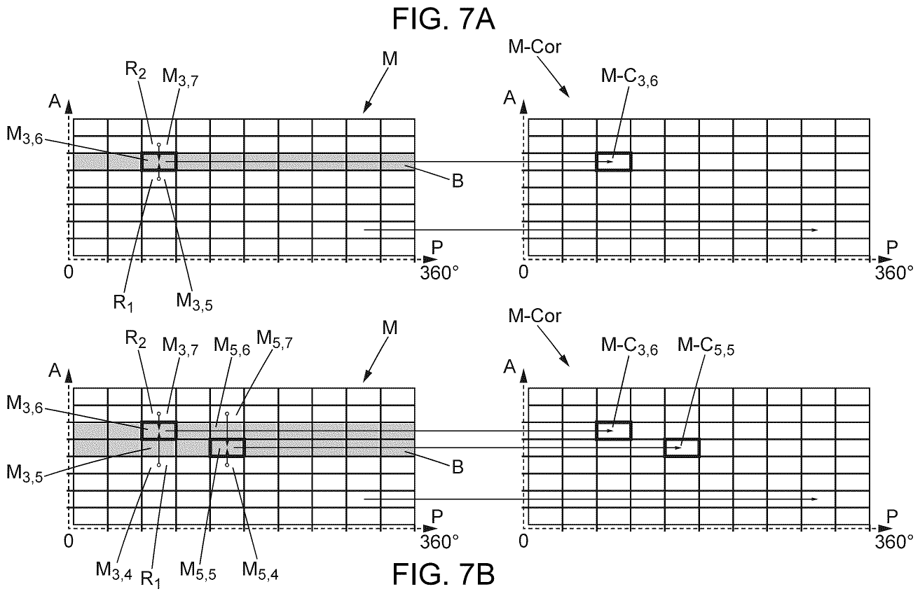

FIG. 7A shows the step of replacing an element of the noisy zone B. This noisy zone B is shown in grey.

On this part A, the noisy zone B relates to a single range of amplitude of the signal, which is the sixth range.
Considering the element M_{3,6} of the noisy zone B corresponding to the third phase value range, the first reference element R1 is the element adjacent to the noisy zone B, not belonging to the noisy zone B, and corresponding to the lower amplitude range, i.e. the element M_{3,5}.
For the element M_{3,6}, the second reference element R2 is the element adjacent to the noisy zone B, not belonging to the noisy zone B, and corresponds to the amplitude range above that of the element M_{3,6}, i.e. the element M_{3,7}.
A new value is calculated from the values of these two reference elements and is assigned to the corresponding element of the corrected matrix M-C.
The element M-C_{3,6} of the corrected matrix M-C is obtained by a mathematical operation performed on the elements M_{3,5} and M_{3,7} of the matrix M.
When at least part of the noisy zone B covers a zone corresponding to real partial discharges, the replacement of the values of the noisy zone by a mathematical calculation performed on the values of the adjacent non-noisy elements enables the reconstruction of usable values.
The elements located outside the noisy zone, indicated by the white boxes in FIGS. 7A, 7B, 8A, 8B, 9 are not modified, and their value is assigned without modification to the corrected matrix M-C, as illustrated by the horizontal line.

In the case where the maximum amplitude range forms part of the noisy zone B, there is no element with an amplitude range immediately above the amplitude range of the elements of which the value is to be replaced.

In this case, the second reference element R2 is considered to be identical to the first reference element R1. In other words, the value of each element of the matrix forming part of the noisy zone B is replaced by the value of the nearest element associated with the same phase range, and not forming part of the noisy zone B.

Similarly, when the minimum amplitude range forms part of the noisy zone B, there is no element with an amplitude range immediately below the amplitude range of the elements of which the value is to be replaced. The first reference element R1 is then considered to be identical to the second reference element R2. In other words, the value of each element of the matrix that forms part of the noisy zone is replaced by the value of the nearest element that is associated with the same phase range and is not part of the noisy zone B.

Various statistical quantities can be used to determine the noisy zone B of the matrix M.

According to one embodiment of the method for detecting partial discharges, the first statistical quantity G1 representative of a number of values associated with an amplitude range of the electrical signal S is a mean value Moy of the samples of the electrical signal,
the mean value Moy being determined over a subset of the phase value ranges of the electrical voltage.

In other words, the mean value characterizing an amplitude range can be determined over only a part of the total phase variation interval, i.e. 360°.

According to another embodiment of the method for detecting partial discharges, the first statistical quantity G1 representative of a number of values associated with an amplitude range of the electrical signal S is a mean value Moy of the values of the elements M_{I,j} of the two-dimensional matrix M associated with said amplitude range of the electrical signal S,
the mean Moy being determined over the set of ranges of phase values of the alternating voltage.

In this case, all phase value ranges are taken into account, i.e. the mean is calculated over the entire 0° to 360° interval.

According to one exemplary embodiment of the method, the mean value is a weighted arithmetic mean.
For a set p of elements X₁, X₂, . . . , Xₚ, the weighted arithmetic mean is given by the expression:

$$Mp = \frac{{\sum }_{i = 1}^{p} ( {K}_{i *} {X}_{i )}}{{\sum }_{i = 1}^{p} {K}_{i}} \qquad [ Math . 1 ]$$

where MP is the weighted arithmetic mean,
and K₁, K₂, . . . , Kₚ are the respective weighting factors associated with the elements X₁, X₂, . . . , Xₚ.

According to one particular example, the mean value is the arithmetic mean.

In other words, the weighting coefficients can be identical. The mean value is thus equal to the sum of the values of different elements of the same row, this sum being divided by the number of elements to be taken into account. When the mean is calculated over the set of ranges of phase values, it is the number of columns in the matrix M.

according to another example of implementation, the mean value is the geometric mean.

As with the first statistical quantity, the second statistical quantity G2 can be determined using different methods.

The standard deviation is a possible indicator to quantify the variability of the values of the different elements of the matrix M.
By definition, for a set of values, the standard deviation is the root mean square of the deviations from the mean. It is also the square root of the variance.

Thus, according to one embodiment of the proposed method, the second statistical quantity G2 representative of a variability of the number of values associated with said amplitude range of the electrical signal S is a standard deviation of the values of the elements M_{I,j} of the two-dimensional matrix M associated with said amplitude range of the electrical signal S,
the standard deviation being determined over a subset of the phase value ranges of the alternating voltage.

According to one variant of the proposed method, the second statistical quantity G2 representative of a variability of the number of values associated with said amplitude range of the electrical signal S is a standard deviation of the values of the elements M_{I,j} of the two-dimensional matrix M associated with said amplitude range of the electrical signal S,
the standard deviation being determined over the set of ranges of phase values of the alternating voltage.

In other words, the second statistical quantity G2 can be determined over only a part of the total phase variation interval, or over the entire 0° to 360° interval.

The variance is another possible indicator to quantify the variability of the values of the different elements of matrix M.

By definition, the variance of a set of values is the arithmetic mean of the squares of the deviations from the mean.
Thus, according to another embodiment of the method for detecting partial discharges, the second statistical quantity G2 representative of a variability of the number of values associated with said amplitude range of the electrical signal S is a variance of the samples of the electrical signal,
the variance being determined over a subset of the phase value ranges of the current.

According to another embodiment of the method for detecting partial discharges, the second statistical quantity G2 representative of a variability of the number of values associated with said amplitude range of the electrical signal S is a variance of the samples of the electrical signal,
the variance being determined over the set of ranges of phase values of the current.

By definition, the standard deviation is the square root of variance, so both indicators produce similar results.

According to another embodiment, the second statistical quantity G2 representative of a variability of the number of values associated with said amplitude range of the electrical signal S is a difference between a maximum value Max determined over a subset of the phase value ranges of the electrical voltage and a minimum value min determined over said subset of the phase value ranges of the electrical voltage.

In one variant, the second statistical quantity G2 representative of a variability of the number of values associated with said amplitude range of the electrical signal S is a difference between a maximum value Max determined over the set of value ranges of the phase of the electrical voltage and a minimum value Min determined over the set of value ranges of the phase of the electrical voltage.

The determined difference can be an absolute difference. In other words, the calculation is based on the difference between the value of the highest-value element and the value of the lowest-value element.

The proposed method thus comprises a sub-step of determining the maximum value among a set of elements.
The method also comprises a sub-step of determining the minimum value among this set of elements.

The determined difference can be a relative difference.

In other words, the previously calculated absolute difference is then divided by the highest value between the determined maximum value and the determined minimum value. The difference obtained can be expressed, for example, as a percentage.
Alternatively, the previously calculated absolute difference is then divided by the lowest value between the determined maximum value and the determined minimum value.

The test of belonging to the noisy zone B can also be based on different conditions.

According to one embodiment of the proposed method, in step (iv), an element M_{I,j} of the two-dimensional matrix M forms part of said noisy zone B if:
the first statistical quantity G1, determined for the amplitude range of said element M_{I,j}, is above a first threshold, and
the second statistical quantity G2, determined for the amplitude range of said element M_{I,j}, is below a second threshold.

The noise that is sought to be eliminated, or at least reduced, has the feature of having a relatively high level, this level also being relatively constant according to the phase of the voltage. The amplitude of the noise thus varies relatively little according to the phase of the voltage.

The first condition of having the first statistical quantity G1 above a selected threshold indicates that the absolute noise level is relatively high.
The second condition of having the second statistical quantity G2 below a threshold indicates that the variability of the noise according to the phase is low. The two conditions must be met simultaneously so that the elements concerned of the matrix M are identified as noise.

In other words, the condition for an element M_{I,j} of the two-dimensional matrix M to form part of said noisy zone B is met when the two conditions are met simultaneously:
the first statistical quantity G1, determined for the amplitude range corresponding to this element M.sub._{I,j}, is above a first threshold, and
the second statistical quantity G2, also determined for the amplitude range corresponding to this element M_{I,j}, is below a second threshold.

For a given amplitude range, the test for determining the noisy zone can be performed on a subset of the set of frequency ranges, i.e. only a part of the set of frequency ranges for the test.

The result of the determination test relates to the set of frequency ranges.
Thus, for a given amplitude range, if the frequency ranges used to calculate the criterion for belonging to the noisy zone indicate that these frequency ranges form part of the noisy zone, the other frequency ranges associated with the same amplitude range are also considered to form part of the noisy zone.
In other words, the noisy zone B comprises only complete rows in the acquisition sample matrix.

According to another embodiment of the method for detecting partial discharges, in step (iv), an element M_{I,j} of the two-dimensional matrix M forms part of said noisy zone B if a ratio F1 of:
the first statistical quantity G1, determined for the amplitude range of said element M_{I,j}, and of
the second statistical quantity G2, determined for the amplitude range of said element M_{I,j},
   is above a predetermined third threshold Th.

Rather than having two different conditions, each based on one of the statistical quantities, a condition based on a ratio of these two statistical quantities can be used. A single threshold must be defined, which makes it easier to calibrate the method.

According to an alternative embodiment of the method for detecting partial discharges, in step (iv), an element M_{I,j} of the two-dimensional matrix M forms part of said noisy zone B if a ratio F1 of:
the first statistical quantity G1, determined for the amplitude range of said element M_{I,j}, and of
the maximum value between:
   the second statistical quantity G2, determined for the amplitude range of said element M_{I,j}, and
   a predetermined constant c,
      is above a predetermined third threshold Th.

The ratio F1 is thus given by the mathematical expression:

$$F 1 = \frac{G 1}{Max ( G 2 , c )} \qquad [ Math . 2 ]$$

The ratio F1 characterizes an amplitude range Aⱼ of the matrix M, each amplitude range therefore having its own value of the ratio F1.

By taking the maximum between the second statistical quantity G2 and a constant value c, the cases that risk leading to indeterminacy are eliminated. Indeterminacy is understood to mean the ratios, or fractions, wherein both the numerator and the denominator of the fraction formed are close to zero.

The predetermined constant c is equal, for example, to one hundredth of the number of amplitude ranges of the two-dimensional matrix M, rounded up to the next integer.

The predetermined constant c is equal, for example, to 1.

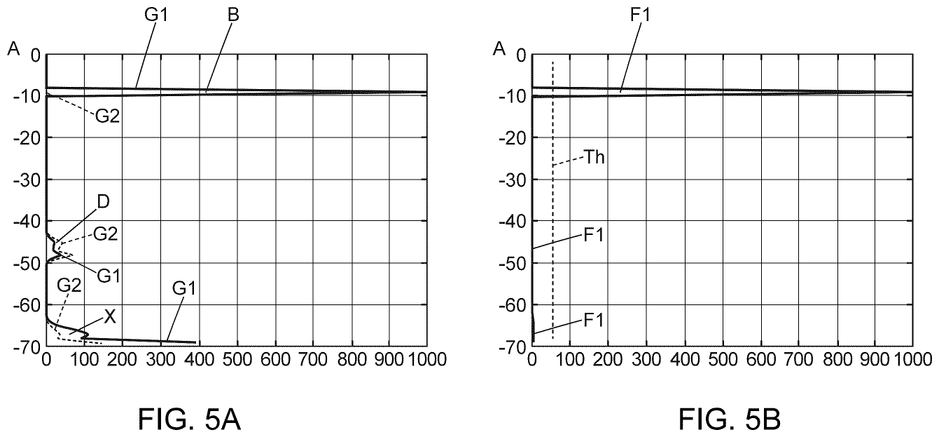

FIG. 5A and FIG. 5B show the behaviour of the statistical quantities G1 and G2, calculated on the matrix shown in FIG. 3.

FIG. 6A and FIG. 6B illustrate the behaviour of the statistical quantities G1 and G2, calculated on the matrix of part A of FIG. 4A and FIG. 4B.

In FIG. 5A, the statistical quantity G1 corresponds to the mean, determined over the set of ranges of phase values. The statistical quantity G2 corresponds to the standard deviation, again determined over the set of ranges of phase values.

The curve denoted F1 corresponds to the ratio of G1 and G2, i.e. the division of G1 by G2, i.e. the mean divided by the standard deviation.
In the zone denoted by the sign D, corresponding to real partial discharges, the standard deviation G2 and the mean G1 are of the same order of magnitude, being around 50.
In the zone denoted X, the mean is higher than in the zone D, and here too the mean G1 and the standard deviation G2 are of the same order of magnitude. The mean G1 is greater than the standard deviation G2.
In the noisy zone B, the mean G1 is significantly higher, in the order of 1000 samples per phase value range, and the standard deviation G2 is very low, having a value of less than 1 and coinciding with the vertical axis of the amplitude A.
In the zone B, the value of G2 used to calculate the ratio of G1 to G2 is therefore limited by the maximum value c, which here is equal to 1.
FIG. 5B represents the calculated value F1 of the ratio of G1 and G2. The value chosen for G2 being equal to 1, the ratio F1 is equal to the mean G1.
In the zone D and the zone X, the mean G1 and the standard deviation G2 are of the same order of magnitude, so that the ratio F1 assumes a value of at most a few units.
With a scale allowing the ratio F1 to be clearly visualized in the noisy zone B, the ratio F1 coincides, for the zone D, with the thickness of the vertical axis A, and also coincides more or less with the zone X.

The vertical dotted line indicates the value of the threshold Th. Since the difference in the ratio F1 between the noisy zone B and the other non-noisy zones D, X is very substantial, the distinction between the different zones is very easy to make.

The zones for which the ratio F1 is above the chosen threshold Th form part of the noisy zone B, and the zones for which the ratio F1 is less than the chosen threshold Th do not form part of the noisy zone B. so that these zones are outside the noisy zone

B, and the values of the corresponding elements of the matrix are retained without modification.

In FIG. 6A and FIG. 6B, the noisy zone B covers a plurality of amplitude ranges, as can be seen in FIG. 6A.

The mean value G1 is thus lower than in the case of FIG. 5A and FIG. 5B, and the standard deviation G2 is higher.
The ratio F1, shown in FIG. 6B, therefore assumes lower values than in FIG. 5A and FIG. 5B.
As above, the different zones can be easily distinguished.

Two possible choices of thresholds are illustrated in FIG. 6B.

With the value Th1, all amplitude ranges between −10 and −22 have a G1 to G2 ratio value greater than the value Th1. The noisy zone B thus comprises contiguous amplitude ranges.
By choosing the value Th2, higher than Th1, for the limit threshold, some of the amplitude ranges between −10 and −22 have a value of the G1 to G2 ratio lower than the chosen value of the threshold Th2. The condition of belonging to the noisy zone B is therefore not met, and these zones are considered to be outside the noisy zone B. The noisy zone B thus comprises a first band of contiguous amplitude ranges and a second band of contiguous amplitude ranges, these two bands being separated by a band of amplitude ranges that do not form part of the noisy zone B.
The sign B_Th1 denotes the noisy zone in the case where the value Th1 is used for the test of belonging to the noisy zone, and the sign B_Th2 denotes the noisy zone if the value Th2 is used.

According to the illustrated embodiment of the method for detecting partial discharges, in step (iv), the noisy zone B of the two-dimensional matrix M comprises the set of ranges of phase values of the current.

In other words, the statistical criterion used to identify the noisy zone B can use only some of the frequency ranges, for a given amplitude range. If the condition of belonging to the noisy zone B is met, the set of ranges of phase values associated with an amplitude range A form part of the noisy zone B.

In other words, in the example shown, the noisy zone B comprises complete rows, i.e. covering the phase range 0° to 360°.

Step (v) of the proposed method will now be detailed, wherein the values forming part of the previously identified noisy zone B are replaced by other values.

According to one embodiment of the method for detecting partial discharges, in step (v), the value of each element M_{I,j} of the two-dimensional matrix M forming part of the noisy zone B is replaced by a weighted mean of the value of the element M_{I,j-1} associated with:
the same range P_{I} of values of the phase of the alternating voltage, and with
the amplitude range Aⱼ₋₁ immediately below the amplitude range Aⱼ of said element M_{I,j},
   and the value of the element M_{I,j+1} associated with:
the same range P_{I} of values of the phase of the alternating voltage, and with
the amplitude range Aⱼ₊₁ immediately above the amplitude range Aⱼ of said element M_{I,j}.

FIG. 7A illustrates this step.

The noisy zone B is indicated by the shaded line associated with the sixth amplitude range.
The element M_{3,6}, corresponding to the third phase value range, is considered.
The element M_{3,7} corresponding to the same phase range and to the amplitude range immediately above that of element M_{3,6} is located outside the noisy zone B. Similarly, the element M_{3,5} corresponding to the same phase range and to the amplitude range immediately below that of the element M_{3,6} is also located outside the noisy zone B. These two elements are therefore used to provide a replacement value, referred to as the denoised value, to the element M_{3,7}. The result of the mathematical operation between M_{3,7} and M_{3,5} forms the element M-C_{3,6} of the corrected matrix M-C. The same processing is applied to the other elements of the same row, i.e. the sixth amplitude range.
The zones of the two-dimensional matrix M which do not form part of the noisy zone B, i.e. the zones for which the criterion of belonging to the noisy zone is not verified, are not subjected to any processing. The values of the elements of these non-noisy zones are therefore copied without modification without the corrected matrix M-C.

The weighting coefficients can be different. In other words, greater importance can be attached to one of the two elements surrounding the element of which the value is corrected in order to attenuate the noise.

The weighting factors can be identical. In other words, the weighted mean can be the arithmetic mean.

In this case, the value of the element M_{I,j} is replaced by the sum divided by two of the element M_{I,j-1} and the element M_{I,j+1}.

In this particular case, in step (v), the value of each element M_{I,j} of the two-dimensional matrix M that forms part of the noisy zone B is replaced by an arithmetic mean of:
the value of the element M_{I,j-1} associated with the same range P_{I} of phase values of the alternating voltage, and with the amplitude range Aⱼ₋₁ immediately below the amplitude range Aⱼ of said element M_{I,j} and of
the value of the element M_{I,j+1} associated with the same range P_{I} of phase values of the alternating voltage, and with the amplitude range Aⱼ₊₁ immediately above the amplitude range Aⱼ of said element M_{I,j}.

In this case, the two elements surrounding the noisy zone element have the same importance in determining the corrected value. The calculations to be performed are simpler than with a weighted mean wherein the coefficients differ from each other.

The mean can be the geometric mean.

In FIG. 7B, the noisy zone B comprises two adjacent, i.e. consecutive, amplitude ranges. The noisy zone B is thus indicated by two contiguous shaded lines.

The element M_{3,6} is considered, corresponding to the third phase value range and the highest amplitude range of the noisy zone.
The element M_{3,7} corresponding to the same phase range and to the amplitude range immediately above that of the element M_{3,6} is situated outside the noisy zone B. This element can therefore be used to determine the corrected value.
The element M_{3,5} corresponding to the same phase range and to the amplitude range immediately below that of the element M_{3,6} is also part of the noisy zone B, and therefore cannot be used to determine the corrected value.
The element M_{3,4} corresponding to the same phase range and to the amplitude range two ranks below that of the element M_{3,6} is outside the noisy zone B. This element is the element with an amplitude range below that of the noisy element which is the nearest usable element.

The replacement value of the element M_{3,6}, referred to as the denoised value, is therefore calculated from the value of the element M_{3,7} and from the value of the element M_{3,4}.

The result of the mathematical operation between M_{3,7} and M_{3,4} thus forms the element MC_{3,6} of the corrected matrix M-C. As above, the same processing is applied to the other elements of the same row.

The element M_{5,5}, which forms part of the lowest amplitude range of the noisy zone B, will now be considered.

The element M_{5,4} corresponding to the same phase range and to the amplitude range immediately below that of the element M_{5,5}, is located outside the noisy zone B, and can therefore be used to determine the corrected value.
The element M_{5,6} corresponding to the same phase range and to the amplitude range immediately above that of the element M_{5,5} is also part of the noisy zone B, and therefore cannot be used to determine the corrected value.
The element M_{5,7} corresponding to the same phase range and to the amplitude range two ranks above that of the element M_{5,5} is outside the noisy zone B. This element is the element with an amplitude range above that of the noisy element M_{5,5} which is the nearest usable element.
The replacement value of the element M_{5,5}, referred to as the denoised value, is therefore calculated from the value of the element M_{5,7} and from the value of the element M_{5,4}.
The result of the mathematical operation between M_{5,7} and M_{5,4} forms the element M-C_{5,5} of the corrected matrix M-C. As above, the same processing is applied to the other elements of the same row.
All the elements of the noisy zone B are thus processed in the same way. Only two elements of the corrected matrix M-C have been illustrated in order to simplify the figure.

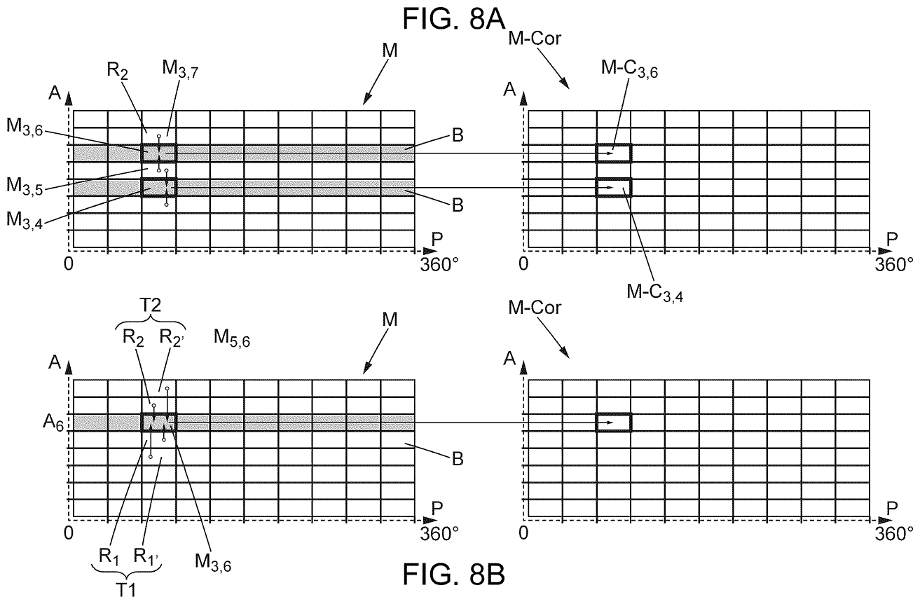

FIG. 8A illustrates a case wherein the noisy zone B comprises two non-contiguous amplitude ranges.

The element M_{3,4} and the element M_{3,6} both form part of the noisy zone B.
The element M_{3,5} separating these two elements is situated outside this noisy zone B, and does not therefore form part of it.
The element M_{3,5} is used to determine the replacement value of the element M_{3,4} and the element M_{3,6}. The element M_{3,5} is the element with the higher amplitude range for M_{3,4} and is the element with the lower amplitude range element for M_{3,6}.
The two shaded lines of the matrix M are processed in the same way.

The replacement value of an element in the noisy zone B can be determined from more than two values surrounding that element in the noisy zone.

For example, according to one embodiment of the proposed method, for each element M_{I,j} of the two-dimensional matrix M forming part of said noisy zone B, the value of said element M_{I,j} is replaced by the result of a mathematical function of at least:
a group of first elements of the two-dimensional matrix M situated outside the noisy zone B, referred to as the group T1 of first reference elements, each element of the group T1 of first reference elements being respectively associated with an amplitude range below the amplitude range of said element M_{I,j}, and
a group of second elements of the two-dimensional matrix M situated outside the noisy zone B, referred to as the group T2 of second reference elements, each element RI of the group T2 of second reference elements being respectively associated with an amplitude range above the amplitude range of said element M_{I,j}.

According to one embodiment, the amplitude ranges of the group T1 of first reference elements are consecutive ranges, and
the amplitude ranges of the group T2 of second reference elements are consecutive ranges.

According to one embodiment, for each element M_{I,j} of the two-dimensional matrix M forming part of said noisy zone B:
each element of the group T1 of first reference elements is respectively associated with the same value range of the phase P of the electrical voltage as said element M_{I,j}, and:
each element of the group T2 of second reference elements is respectively associated with the same value range of the phase P of the electrical voltage as said element M.sub._{I,j}.

FIG. 8B shows schematically this embodiment, in the case where the group T1 comprises two first reference elements R1 and R1′, and where the second group T2 also comprises two second reference elements R2 and R2′.

The first two reference elements R1 and R1′ correspond to the two consecutive amplitude ranges located outside the noisy zone B, and corresponding to amplitude ranges below that of the noisy zone, denoted A₆.
The two second reference elements R2 correspond to the two consecutive amplitude ranges located outside the noisy zone B, and corresponding to amplitude ranges above the amplitude range A₆ of the noisy zone.
Each group T1, T2 can further comprise more than two elements. For example, each group T1, T2 can comprise three elements.
The group T1 of first reference elements and the group T2 of second reference elements can comprise different numbers of elements.
These two cases have not been shown.

According to another embodiment of the proposed method, for each element M_{I,j} of the two-dimensional matrix M forming part of said noisy zone B:
at least one element of the group T1 of first reference elements is associated with a value range of the phase P different from the value range of the phase of said element M_{I,j}, and:
at least one element of the group T2 of second reference elements is associated with a value range of the phase P different from the value range of the phase of said element M_{I,j}.

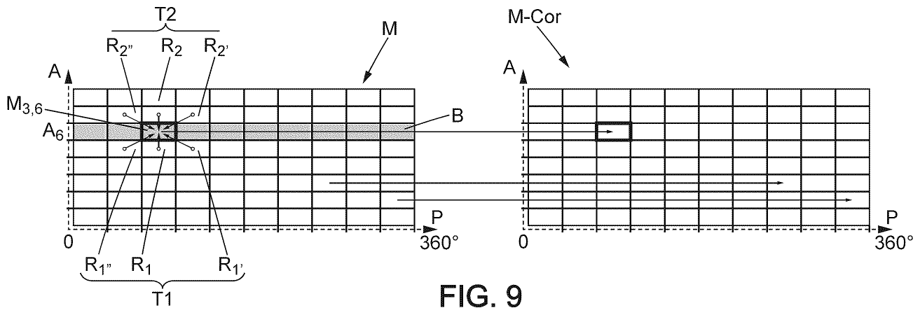

FIG. 9 shows schematically an example of this embodiment.

In this example, the group T1 of first reference elements comprises, for each element M_{I,j} of the noisy zone B: the element associated with the phase value range below that of the element M_{I,j}, the element associated with the phase value range below that of the element M_{I,j}, and the element associated with the same phase value range as that of the element M_{I,j}.
By way of illustration for the element M_{3,6}: the group T1 of first reference elements comprises the element R1″ associated with the phase value range below that of the element M_{3,6}, the element R1′ associated with the phase value range above that of the element M_{3,6}, and the element R1 associated with the same phase value range below that of the element M_{3,6}.
Similarly, for the element M_{3,6}, the group T2 of second reference elements comprises the element R2″ associated with the phase value range below that of the element M_{3,6}, the element R2′ associated with the phase value range above that of the element M_{3,6}, and the element R2 associated with the same phase value range below that of the element M_{3,6}.
In this example, the six elements nearest to an element M_{I,j} of the noisy zone B, while being outside the noisy zone B, are taken into account in calculating the replacement value of this element M_{I,j}.

For the element in the first phase range, there is no element corresponding to the lower range. In this case, only the element corresponding to the same range and the element corresponding to the higher range are taken into account.

Similarly, the element in the noisy zone associated with the last value range has no adjacent element corresponding to a higher value range. Only the element corresponding to the same range and the element corresponding to the lower range are then taken into account.

In the example shown in FIG. 9, the elements of the group T1 of first reference elements are associated with consecutive phase value ranges, i.e. which follow one another without being separated by another phase range.

The same applies to the elements of the group T2 of second reference elements.
It is conceivable to choose the elements of the group T1 of first reference elements such that two successive elements of this group are separated by a phase range of which the element itself does not form part of the group T1.
Similarly, the elements of the group T2 of second reference elements can be chosen such that two successive elements of the group T2 are separated by a phase range of which the element does not itself form part of the group T1.
This case has not been shown.

Mathematical functions other than those already listed can be used to determine the replacement value of each element of the two-dimensional matrix M which forms part of the noisy zone B.

For example, a polynomial in a plurality of variables can be used.

The variables are the elements of the group T1 of first reference elements and the elements of the group T2 of second reference elements.

A non-linear interpolation among the elements of the group T1 of first reference elements and the elements of the group T2 of second reference elements can also be used.

A cubic spline function interpolation, for example, can be used.

Steps (i) to (v) form steps of a method for reducing the noise of an electrical signal representative of a partial discharge in the insulator of a medium-voltage or high-voltage electrical conductor.

Once the corrected two-dimensional matrix M_CoR has been established, the step (vi) of detecting partial discharges is carried out from this corrected matrix.

Various detection algorithms based on the exploitation of a ‘PRPD’ matrix, known to a person skilled in the art, can be used.

For example, the method listed in the article entitled “The effects of superimposed impulse transients on partial discharge in XLPE cable joint”, published in the journal Electrical Power and Energy Systems 110 (2019) 497-509, can be employed.
Other examples are provided by Edward Gulski's thesis paper entitled “Computer aided recognition of partial discharges using statistical tools”.

The method has been described in the case where partial discharge detection is performed for only one of the three electrical conductors of the electrical device 20.

The proposed method can be applied simultaneously to each of the electrical conductors, so as to protect the electrical device 20 as effectively as possible.

The invention therefore also relates to a method for detecting partial discharges in a medium-voltage or high-voltage electrical device 20,
the electrical device 20 comprising:
   a first electrical conductor 1 comprising an insulator 2,
   a second electrical conductor 1′ comprising an insulator 2′,
   a third electrical conductor 1″ comprising an insulator 2″,
the first electrical conductor 1, the second electrical conductor 1′ and the third electrical conductor 1″ corresponding respectively to a first phase, a second phase and a third phase of an electrical network,
wherein a method as described above is carried out for the insulator 2, 2′, 2″ of each electrical conductor 1, 1′, 1″.
In other words, the proposed method is simultaneously carried out to detect partial discharges in the insulator 2 of the first electrical conductor 1, in the insulator 2′ of the second electrical conductor 1′, and in the insulator 2″ of the third electrical conductor 1″.

The same method for detecting partial discharges can be applied to each of the three electrical conductors 1, 1′, 1″.

The hardware necessary for detecting partial discharges forms a device 10 for detecting partial discharges.

The device 10 for detecting partial discharges comprises:
a sensor 3 configured to supply an electrical signal S representative of a partial discharge in an insulator 2 of an electrical conductor 1,
an electronic control unit 5 configured to carry out the method for detecting partial discharges as described above.

In order to be able to ensure simultaneous detection on the electrical conductors respectively associated with the three phases, the device 10 for detecting partial discharges comprises:
three sensors 3, 3′, 3″, each sensor 3, 3′, 3″ being configured to supply an electrical signal S, S′, S″ representing a partial discharge in an insulator 2, 2′, 2″ of an electrical conductor 1,
an electronic control unit 5 configured to carry out the method for detecting partial discharges as described above.

The electronic control unit 5 comprises three data acquisition channels, each acquisition channel respectively processing the signal of a sensor 3, 3′, 3″.

1. A method for detecting partial discharges in an insulator of an electrical conductor of a medium-voltage or high-voltage electrical device, the electrical conductor being subjected to an alternating voltage,
the method comprising the steps of:
(i) successively acquiring a set of samples of an electrical signal representative of a partial discharge in the insulator of the electrical conductor,
(ii) for each sample in the set of samples, determining the value of the phase of the alternating voltage,
(iii) establishing a two-dimensional matrix of elements, wherein:
a first dimension of the two-dimensional matrix corresponds to a set of ranges of values of the phase of the alternating voltage,
a second dimension of the two-dimensional matrix corresponds to a set of amplitude ranges of the samples of the set of samples of the electrical signal, and
the value of each element of the two-dimensional matrix is equal to the number of samples within the value range of the phase of the alternating voltage associated with said element of the two-dimensional matrix and comprised within the amplitude range of the electrical signal associated with said element of the two-dimensional matrix,
(iv) determining in the established two-dimensional matrix a portion corresponding to electrical noise, known as the noisy zone, according to a condition based on at least:
a first statistical quantity representative of a number of values associated with an amplitude range of the electrical signal,
a second statistical quantity representative of a variability of the number of values associated with said amplitude range of the electrical signal,
(v) for each element of the two-dimensional matrix forming part of said noisy zone, replacing the value of said element by the result of a mathematical function of at least:
a first element of the two-dimensional matrix located outside the noisy zone, referred to as the first reference element, the first reference element being associated with:
the same value range of the phase of the electrical voltage as said element, and associated with
an amplitude range below the amplitude range of said element, and
a second element of the two-dimensional matrix located outside the noisy zone, referred to as the second reference element, the second reference element being associated with:
the same value range of the phase of the electrical voltage as said element, and associated with
an amplitude range above the amplitude range of said element,
in order to establish a two-dimensional corrected matrix of elements,
(vi) detecting the presence of partial discharges or the absence of partial discharges in the insulator from the corrected matrix established.

2. The method for detecting partial discharges according to claim 1, wherein, for each element of the two-dimensional array forming part of said noisy zone:
the first reference element is associated with the amplitude range immediately below the amplitude range of said element, and
the second reference element is associated with the amplitude range immediately above the amplitude range of said element.

3. The method for detecting partial discharges according to claim 1, wherein, for each element of the two-dimensional matrix forming part of said noisy zone, the value of said element is replaced by the result of a mathematical function of at least:
a group of first elements of the two-dimensional matrix located outside the noisy zone, referred to as the group of first reference elements, each element of the group of first reference elements being respectively associated with an amplitude range below the amplitude range of said element, and
a group of second elements of the two-dimensional matrix located outside the noisy zone, referred to as the group of second reference elements, each element of the group of second reference elements being respectively associated with an amplitude range above the amplitude range of said element.

4. The method for detecting partial discharges according to claim 3,
wherein the amplitude ranges of the group of first reference elements are consecutive ranges, and
the amplitude ranges of the group of second reference elements are consecutive ranges.

5. The method for detecting partial discharges according to claim 3, wherein, for each element of the two-dimensional array forming part of said noisy zone,
each element of the group of first reference elements is respectively associated with the same value range of the phase of the electrical voltage as said element, and:
each element of the group of second reference elements is respectively associated with the same value range of the phase of the electrical voltage as said element.

6. The method for detecting partial discharges according to claim 3, wherein, for each element of the two-dimensional matrix forming part of said noisy zone,
at least one element of the group of first reference elements is associated with a value range of the phase different from the value range of the phase of said element, and:
at least one element of the group of second reference elements is associated with a value range of the phase which differs from the value range of the phase of said element.

7. The method for detecting partial discharges according to claim 1, wherein the first statistical quantity representative of a number of values associated with an amplitude range of the electrical signal is a mean value of the values of the elements of the two-dimensional matrix associated with said amplitude range of the electrical signal,
the mean being determined over a subset of the phase value ranges of the alternating voltage.

8. The method for detecting partial discharges according to claim 1, wherein the second statistical quantity representative of a variability of the number of values associated with said amplitude range of the electrical signal is a standard deviation of the values of the elements of the two-dimensional matrix associated with said amplitude range of the electrical signal,
the standard deviation being determined over a subset of the phase value ranges of the alternating voltage.

9. The method for detecting partial discharges according to claim 1, wherein, in step (iv), an element of the two-dimensional matrix forms part of said noisy zone if:
the first statistical quantity, determined for the amplitude range of said element, is above a first threshold, and
the second statistical quantity, determined for the amplitude range of said element, is below a second threshold.

10. The method for detecting partial discharges according to claim 1, wherein, in step (iv), an element of the two-dimensional matrix forms part of said noisy zone if a ratio of:
the first statistical quantity, determined for the amplitude range of said element, and of
the maximum value between:
the second statistical quantity, determined for the amplitude range of said element, and
a predetermined constant,
is above a predetermined third threshold.

11. The method for detecting partial discharges according to claim 1, wherein, in step (iv), the noisy zone of the two-dimensional matrix comprises the set of ranges of phase values of the voltage.

12. The method for detecting partial discharges according to claim 1, wherein, in step (v), the value of each element of the two-dimensional matrix forming part of the noisy zone is replaced by a weighted mean of the value of the element associated with:
the same range of values of the phase of the alternating voltage, and with
the amplitude range immediately below the amplitude range of said element,
and of the value of the element associated with:
the same range of values of the phase of the alternating voltage, and with
the amplitude range immediately above the amplitude range of said element.

13. The method for detecting partial discharges according to claim 1, wherein the scale of the units of the electrical signal representative of a partial discharge in the insulator of the electrical conductor is a logarithmic scale.

14. A device for detecting partial discharges, comprising:
a sensor configured to supply an electrical signal representative of a partial discharge in an insulator of an electrical conductor,
an electronic control unit configured to carry out the method for detecting partial discharges according to claim 1.

15. An electrical device comprising:
three electrical conductors corresponding respectively to three phases of a three-phase medium-voltage or high-voltage electrical network,
three insulators, each insulator surrounding an electrical conductor respectively,
three sensors, each sensor being respectively configured to supply an electrical signal representative of a partial discharge in the insulator of an electrical conductor,
an electronic control unit configured to carry out, for each insulator the method for detecting partial discharges according to claim 1.
